(19) United States
(12) Patent Application Publication
(10) Pub. No.: US 2024/0040741 A1
(43) Pub. Date: Feb. 1, 2024

(54) COLD PLATE WITH INTEGRATED CONNECTORS FOR USE IN AN AUTONOMOUS VEHICLE COMPUTING SYSTEM

(71) Applicant: GM Cruise Holdings LLC, San Francisco, CA (US)

(72) Inventors: Brian Schlotterbeck, Berkeley, CA (US); Adli Nureddin, Novato, CA (US)

(73) Assignee: GM Cruise Holdings LLC, San Francisco, CA (US)

(21) Appl. No.: 17/878,899

(22) Filed: Aug. 1, 2022

(51) Int. Cl. H05K 7/20

(52) U.S. Cl. CPC H05K 7/20254; H05K 7/20881; H05K 1/0209

(57) ABSTRACT

An apparatus is described and includes a printed circuit board (PCB) including at least one connector on a first surface thereof; a cold plate connected to the first surface of the PCB. The cold plate includes at least one tube disposed in a first portion of the cold plate and at least one opening for receiving the at least one connector therethrough, the at least one opening disposed in a second portion of the cold plate. The apparatus further includes a housing including a lower housing portion for supporting the PCB and the cold plate such that the PCB is between the lower housing portion and the cold plate and an upper housing portion over the first portion of the cold plate. The second portion of the cold plate is exposed outside the upper housing portion when the upper and lower housing portions are fastened together.

### BACKGROUND

### Technical Field

The present disclosure relates generally to autonomous vehicles (AVs) and, more specifically, to a cold plate with integrated connectors for heat dissipation in a computing system of an AV.

### Introduction

An AV is a motorized vehicle that can navigate without a human driver. An exemplary AV can include various sensors, such as a camera sensor, a light detection and ranging (LIDAR) sensor, and a radio detection and ranging (RADAR) sensor, among others. The sensors collect data and measurements that the AV can use for operations such as navigation. The sensors can provide the data and measurements to an internal computing system of the AV, which can use the data and measurements to control a mechanical system of the AV, such as a vehicle propulsion system, a braking system, or a steering system. Typically, the sensors are mounted at fixed locations on the AVs.

### BRIEF DESCRIPTION OF THE DRAWINGS

The various advantages and features of the present technology will become apparent by reference to specific implementations illustrated in the appended drawings. A person of ordinary skill in the art will understand that these drawings only show some examples of the present technology and would not limit the scope of the present technology to these examples. Furthermore, the skilled artisan will appreciate the principles of the present technology as described and explained with additional specificity and detail through the use of the accompanying drawings in which:

FIG. 1 illustrates a simplified exploded perspective view of an example system including a cold plate with integrated connectors for heat dissipation in a computer system for an AV, according to some examples of the present disclosure;

FIG. 2 illustrates a simplified perspective view of the cold plate of the example system illustrated in FIG. 1, according to some examples of the present disclosure;

FIG. 3 illustrates a simplified non-exploded view of the example system illustrated in FIG. 1, according to some examples of the present disclosure;

FIG. 4A illustrates a simplified perspective view of a portion of another example system including a cold plate with integrated connectors for heat dissipation in a computer system for an AV, according to some examples of the present disclosure;

FIG. 4B illustrates a cutaway view of a section of the portion of the example system illustrated in FIG. 4A, according to some embodiments of the present disclosure;

FIG. 5 illustrates a more detailed view of a connector of the example system illustrated in FIG. 4B, according to some embodiments of the present invention;

FIG. 6 illustrates an example system environment that can be used to facilitate autonomous vehicle (AV) dispatch and operations, according to some aspects of the disclosed technology; and

FIG. 7 is a schematic representation of an AV with an example system for including a cold plate with integrated connectors for heat dissipation in a computer system, according to some examples of the present disclosure.

### DETAILED DESCRIPTION

### Overview

The detailed description set forth below is intended as a description of various configurations of the subject technology and is not intended to represent the only configurations in which the subject technology can be practiced. The appended drawings are incorporated herein and constitute a part of the detailed description. The detailed description includes specific details for the purpose of providing a more thorough understanding of the subject technology. However, it will be clear and apparent that the subject technology is not limited to the specific details set forth herein and may be practiced without these details. In some instances, structures and components are shown in block diagram form in order to avoid obscuring the concepts of the subject technology.

An AV contains within it many integrated circuit (IC) devices such as microprocessors, microcontrollers, and the like. These IC devices perform various functions that enable the AV to operate without a human driver or with little human assistance. Due to various technological factors beyond the scope of this disclosure, many of these IC devices are configured to operate effectively and reliably only under specific temperature conditions or within a specific temperature range. Operating outside that temperature range can potentially result in thermomechanical failure of such IC devices. Thus, unlike computing devices inside climate-controlled datacenters and homes, due to the manner in which typical vehicles are used, for example, parked outside exposed to the elements in all weather conditions, IC devices inside these vehicles may experience temperatures outside the specified temperature range for substantial periods of time. IC devices in such vehicles under such environmental conditions may fail if the IC devices have to power on several times and/or for several days at such extreme hot or cold temperatures.

When an IC device is powered on, it generates heat that must be removed effectively to prevent catastrophic failure. Indeed, microprocessors and other such IC devices that perform complex computations may heat up at such a high rate that they have to be cooled using liquid coolants to prevent thermomechanical failure.

Accordingly, examples of the present disclosure provide a cold plate for heat dissipation in an AV computer system The cold plate of the present disclosure incorporates one or more connectors, such as network (e.g., Ethernet) connectors, power connectors, data connectors, and other types of connectors, via a top surface thereof. The present disclosure offers advantages over previous cold plate designs for AV computer systems in that it reduces stress on the connectors and the cold plate caused by movement of the AV through beneficial use of gaskets between outside surfaces of the connector and inside surfaces of the corresponding cold plate opening through which the connector extends Additionally, the design of the present disclosure significantly reduces assembly costs associated with designs in which connectors are disposed on an outside edge, rather than a top surface, of the cold plate.

The following detailed description presents various descriptions of specific certain embodiments. However, the innovations described herein can be embodied in a multitude of different ways, for example, as defined and covered by the claims and/or select examples. In the following description, reference is made to the drawings, in which like reference numerals can indicate identical or functionally similar elements. It will be understood that elements illustrated in the drawings are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

The following disclosure describes various illustrative embodiments and examples for implementing the features and functionality of the present disclosure. While particular components, arrangements, and/or features are described below in connection with various example embodiments, these are merely examples used to simplify the present disclosure and are not intended to be limiting. It will of course be appreciated that in the development of any actual embodiment, numerous implementation-specific decisions must be made to achieve the developer's specific goals, including compliance with system, business, and/or legal constraints, which may vary from one implementation to another. Moreover, it will be appreciated that, while such a development effort might be complex and time-consuming; it would nevertheless be a routine undertaking for those of ordinary skill in the art having the benefit of this disclosure.

In the drawings, a particular number and arrangement of structures and components are presented for illustrative purposes and any desired number or arrangement of such structures and components may be present in various embodiments. Further, the structures shown in the figures may take any suitable form or shape according to material properties, fabrication processes, and operating conditions. For convenience, if a collection of drawings designated with different letters are present (e.g., FIGS. 10A-10C), such a collection may be referred to herein without the letters (e.g., as “FIG. 10”). Similarly, if a collection of reference numerals designated with different letters are present (e.g., 110a-110e), such a collection may be referred to herein without the letters (e.g., as “110”).

In the Specification, reference may be made to the spatial relationships between various components and to the spatial orientation of various aspects of components as depicted in the attached drawings. However, as will be recognized by those skilled in the art after a complete reading of the present disclosure, the devices, components, members, apparatuses, etc. described herein may be positioned in any desired orientation. Thus, the use of terms such as “above”, “below”, “upper”, “lower”, “top”, “bottom”, or other similar terms to describe a spatial relationship between various components or to describe the spatial orientation of aspects of such components, should be understood to describe a relative relationship between the components or a spatial orientation of aspects of such components, respectively, as the components described herein may be oriented in any desired direction. When used to describe a range of dimensions or other characteristics (e.g., time, pressure, temperature, length, width, etc.) of an element, operations, and/or conditions, the phrase “between X and Y” represents a range that includes X and Y. The terms “substantially,” “close,” “approximately,” “near,” and “about,” generally refer to being within +/−20% of a target value (e.g., within +/−5 or 10% of a target value) based on the context of a particular value as described herein or as known in the art.

As described herein, one aspect of the present technology is the gathering and use of data available from various sources to improve quality and experience. The present disclosure contemplates that in some instances, this gathered data may include personal information. The present disclosure contemplates that the entities involved with such personal information respect and value privacy policies and practices.

Other features and advantages of the disclosure will be apparent from the following description and the claims.

### Example Embodiments

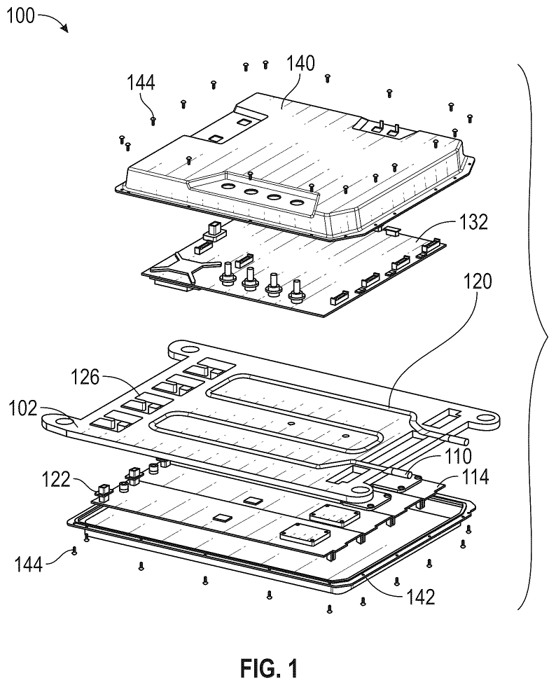

FIG. 1 illustrates a simplified exploded perspective view of an example system 100 that includes a cold plate having integrated connectors for heat dissipation in an AV computer system, according to some examples of the present disclosure. As shown in FIG. 1, a cold plate 102 is configured to be thermally coupled to an IC device 110. In some examples (as shown), cold plate 102 is thermally coupled to IC device 110 by a thermally conductive material. In some examples, thermally conductive material may have adhesive properties. In some examples, thermally conductive material may be soft (e.g., flexible) and compliant. Examples of thermally conductive material include synthetic resins augmented with metallic or inorganic filler materials. In some embodiments, thermally conductive material may extend partially across a contact area between IC device 110 and cold plate 102 merely as an example and not as a limitation. Thermally conductive material may substantially cover the contact area between IC device 110 and cold plate 102 in some examples. Other means of attachment, including brazing, soldering, etc. that provides a thermal path between IC device 110 and cold plate 102 may also be used within the broad scope of the examples.

In many examples, IC device 110 is configured to operate below a maximum operating temperature (e.g., 100° C.), with an optimum load temperature range (e.g., between 55° C. and 75° C.). Above the maximum operating temperature, IC device 110 may experience catastrophic failure, including melting, cracking, and breaking apart. In some examples, IC device 110 is conductively and mechanically coupled to a printed circuit board (PCB) 114 (also known as a motherboard). PCB 114 may comprise various other components not shown in the figure so as not to clutter the drawings. In some examples, IC device 110 is coupled to PCB 114 by solder bonds (not shown) such as ball grid array, land grid array, etc. IC device 110 may be sandwiched between PCB 114 and cold plate 102. In various example, cold-plate 102 is made from a thermally conductive material, such as molded or pressed aluminum, steel, copper, etc. In some examples, cold plate 102 may be shaped and sized to correspond to the shape and size of IC device 110. For example, cold plate 102 may include a cavity or recess into which IC device 110 may fit suitably. In another example, cold plate 102 may partially or entirely surround IC device 110. In yet another example, spacers may be provided on either PCB 114, cold plate 102, or both to provide sufficient space between PCB 114 and cold plate 102 to accommodate IC device 110.

In various examples, cold-plate 102 may comprise tubes 120 configured for flow of a cooling fluid (not shown). In some examples, the cooling fluid may be a liquid coolant used in the AV, such as a 50-50 solution of ethylene glycol and water (e.g., 50% ethylene glycol and 50% water by volume). Any suitable cooling fluid, including deionized water, distilled water, etc. may be used in cold-plate 116 within the broad scope of the examples. In some examples, cold-plate 116 may comprise heat tubes; in yet other examples, cold-plate 102 may comprise a vapor chamber. Any suitable combination of material and design that can facilitate heat transfer from IC device 110 may be used in cold-plate 102 within the broad scope of the examples disclosed herein. In some examples, cooling fluid may circulate in tubes 120 within cold-plate 102 to carry heat away from IC device 110 when IC device 110 is powered on; in some such examples, the cooling fluid may not circulate in tubes 120 when IC device 110 is not powered on.

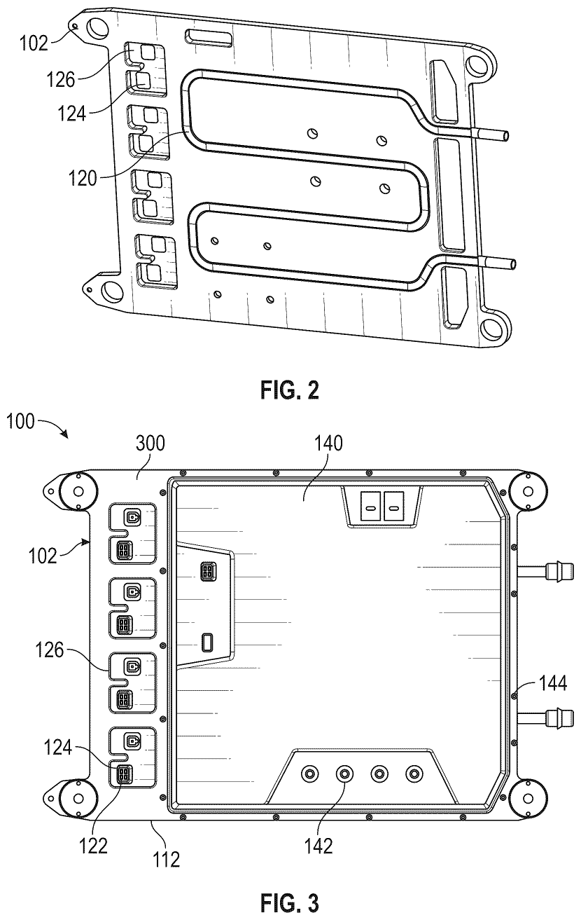

In various examples, PCB 114 includes a plurality of connectors 122, which may comprise one or more of network connectors, power connectors, data connectors, and other types of connectors, for example. In accordance with features of embodiments described herein, and as shown in FIGS. 1 and 2, cold plate includes a plurality of openings 124 through which connectors 122 are received when IC 110 is connected to cold plate 102 as described above. As best shown in FIG. 2, in various examples, openings 124 may be disposed in recesses 200 of cold plate 102 for accommodating a technician's fingers while connecting cables to and/or disconnecting cables from the connectors 122. It will be recognized that placement of openings 124 (as well as underlying connectors 122 accommodated thereby) may be selected so as to maximize heat dissipation by cold plate 102 (e.g., by locating openings 224 away from tubes 120) as well as to minimize and/or prevent structural compromise of cold plate 102 (e.g., by locating the openings away from an outside edge of cold plate 102). As best illustrated in FIG. 2, tubes 120 are located in a first area, or portion, of cold plate 102, which as will be described below is covered by a housing, whereas openings 224 are located in a second area, or portion, of cold plate 102, which as will be described in detail below is exposed and accessible outside of the housing.

Referring again to FIG. 1, system 100 may further include at least one additional IC device (not shown) conductively and mechanically coupled to a bottom (as shown in FIG. 1) side of a second PCB 132 that, like PCB 114, may comprise various other components not shown in the figure so as not to clutter the drawings. In some examples, the at least one additional IC device is coupled to PCB 132 by solder bonds (not shown) such as ball grid array, land grid array, etc. The at least one additional IC device may be sandwiched between PCB 132 and cold plate 102. In some examples, cold plate 102 may be shaped and sized to correspond to the shape and size of the at least one additional IC device. For example, cold plate 102 may include a cavity or recess into which the at least one additional IC device may fit suitably. In another example, cold plate 102 may partially or entirely surround the at least one additional IC device. In yet another example, spacers may be provided on either PCB 132, cold plate 102, or both to provide sufficient space between PCB 132 and cold plate 102 to accommodate the at least one additional IC device.

As with IC 110, cold plate 102 is configured to be thermally coupled to the at least one additional IC device such that, once assembled, cold plate 102 is sandwiched between PCB 114 and PCB 132 and connectors 122 extend through openings 106 in cold plate 102. In some examples (as shown), cold plate 102 is thermally coupled to the at least one additional IC device by a thermally conductive material as described above with respect to thermal coupling of IC 110 and cold plate 102. In some embodiments, thermally conductive material may extend partially across a contact area between the at least one additional IC device and cold plate 102 merely as an example and not as a limitation. Thermally conductive material may substantially cover the contact area between the at least one additional IC device and cold plate 102 in some examples. Other means of attachment, including brazing, soldering, etc. that provides a thermal path between the at least one additional IC device and cold plate 102 may also be used within the broad scope of the examples.

Referring now to FIG. 1 in combination with FIG. 3, system 100 further includes a top housing portion 140 and a bottom housing portion 142 which may be fastened together using fastener members 144, for example, to form a housing for enclosing PCB 114 and PCB 132 and at least a portion of cold plate 102. In particular, and as best shown in FIG. 3, when system 100 is assembled, a portion 300 of cold plate 102 remains uncovered by top housing portion 140 such that connectors 122 are exposed and accessible for connection of cables thereto.

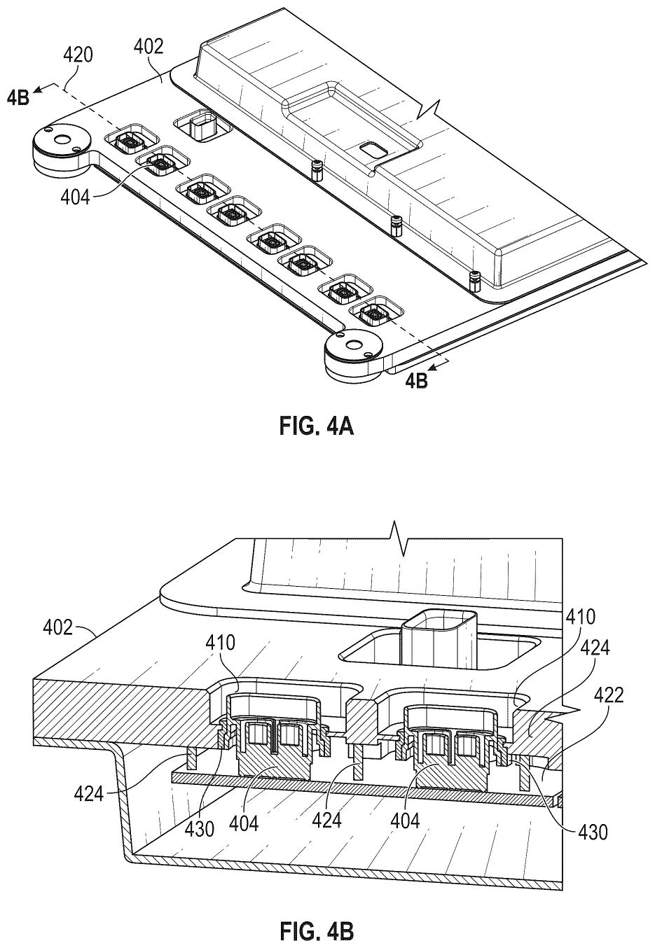

FIG. 4A illustrates a portion of a system 400 that includes a cold plate 402 with integrated connectors 404 for heat dissipation in an AV computer system, according to some examples of the present disclosure. It will be recognized that system 400 is similar in all relevant respects to system 100 (FIGS. 1-3). As shown in FIG. 4, a portion 408 of the cold plate 402 is exposed and connectors 404 extend through openings 410 in exposed cold plate portion 408.

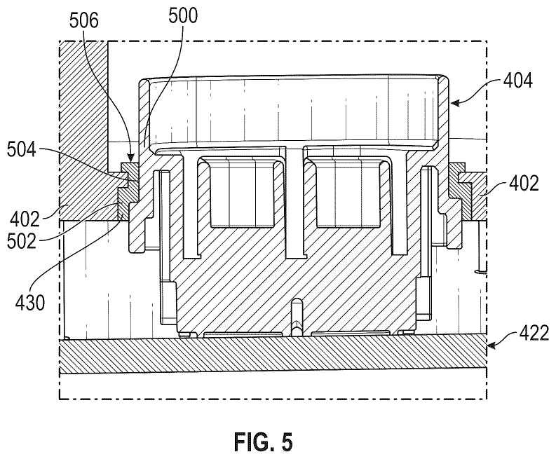

FIG. 4B is a cutaway view of FIG. 4A along a cut line 420. As shown in FIG. 4B, connectors 404 are disposed on a PCB 422 and, as previously noted, are accessible through openings 410 in cold plate 402. As also shown in FIG. 4B, spacers 424 are provided between PCB 422 and cold plate 402 to (among other functions) provide space for and appropriately vertically position (in the illustrated embodiment) connectors 404 within openings 410. In accordance with features of embodiments described herein, and as illustrated in greater detail in FIG. 5, gaskets 430 are provided around connectors 404 in the space between outside surfaces of connectors 404 and inside surfaces of openings 410. In certain embodiments, gaskets 430 may provide one or more of various functions, including providing a seal between connectors 404 and cold plate 402 to prevent dirt and debris from being deposited on PCB 422, and absorbing vibrations caused by movement of the AV that might otherwise negatively impact connectors 404 and/or cold plate 402. Gaskets 430 may also serve to prevent wear and tear on the connectors 404 that might otherwise result from interaction between connectors 404 and cold plate 402 and to provide thermal insulation for connectors 404 from cold plate 402. In a variety of embodiments, gaskets 402 may be constructed of any appropriate material, including but not limited to rubber, silicone, metal, cork, felt, neoprene, nitrile rubber, fiberglass, polytetrafluoroethylene (otherwise known as PTFE or TEFLON® ), and/or a plastic polymer (such as polychlorotrifluoroethylene).

FIG. 5 is a more detailed illustration of one of connectors 404. As best shown in FIG. 5, connector 404 may include a flange 500. As shown in FIG. 5, gasket 430 is disposed in and fills a gap between an edge 502 of cold plate 402 within opening 410 and a surface 504 of flange 500. In various embodiment, gasket 430 may include a portion 506 that overlaps a portion of cold plate 402 in order to provide a better seal against debris and detritus. It will be recognized that a shape of gasket 430 may differ depending on the type of connector deployed and the size and shape of the cold plate opening. In some implementations the gasket 430 is connected (e.g., adhered) to connector 404 prior to assembly of system 100, in which case, gasket forms the seal with the edge of opening 410 upon assembly. In other implementations, the gasket 430 is connected (e.g., adhered) to an inside edge of opening 410 prior to assembly of system 100, in which case, gasket forms the seal with connector 404 upon assembly.

### Example AV Management System

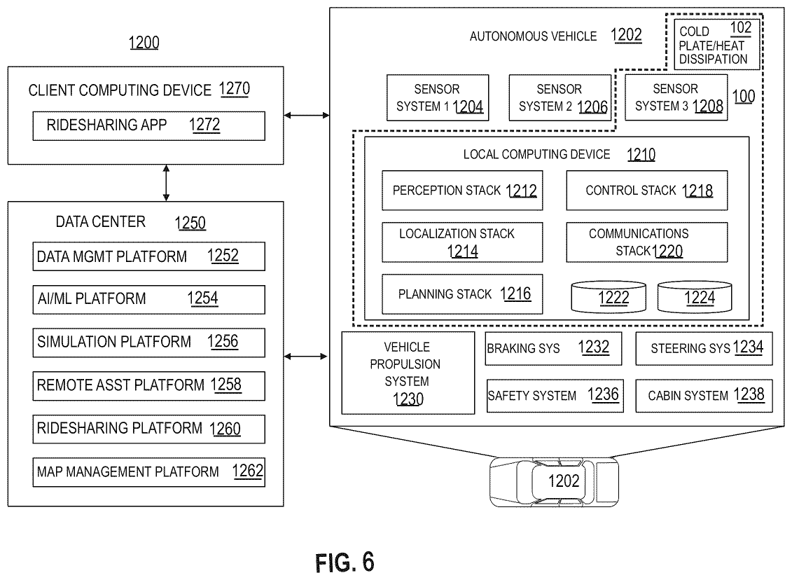

Turning now to FIG. 6, illustrated therein is an example of an AV management system 1200. One of ordinary skill in the art will understand that, for the AV management system 1200 and any system discussed in the present disclosure, there can be additional or fewer components in similar or alternative configurations. The illustrations and examples provided in the present disclosure are for conciseness and clarity. Other examples may include different numbers and/or types of elements, but one of ordinary skill the art will appreciate that such variations do not depart from the scope of the present disclosure.

In this example, the AV management system 1200 includes an AV 1202, a data center 1250, and a client computing device 1270. The AV 1202, the data center 1250, and the client computing device 1270 can communicate with one another over one or more networks (not shown), such as a public network (e.g., the Internet, an Infrastructure as a Service (IaaS) network, a Platform as a Service (PaaS) network, a Software as a Service (SaaS) network, another Cloud Service Provider (CSP) network, etc.), a private network (e.g., a Local Area Network (LAN), a private cloud, a Virtual Private Network (VPN), etc.), and/or a hybrid network (e.g., a multi-cloud or hybrid cloud network, etc.).

AV 1202 can navigate about roadways without a human driver based on sensor signals generated by multiple sensor systems 1204, 1206, and 1208. The sensor systems 1204-1208 can include different types of sensors and can be arranged about the AV 1202. For instance, the sensor systems 1204-1208 can comprise Inertial Measurement Units (IMUS), cameras (e.g., still image cameras, video cameras, etc.), light sensors (e.g., LIDAR systems, ambient light sensors, infrared sensors, etc.), RADAR systems, a Global Navigation Satellite System (GNSS) receiver, (e.g., Global Positioning System (GPS) receivers), audio sensors (e.g., microphones, Sound Navigation and Ranging (SONAR) systems, ultrasonic sensors, etc.), engine sensors, speedometers, tachometers, odometers, altimeters, tilt sensors, impact sensors, airbag sensors, seat occupancy sensors, open/closed door sensors, tire pressure sensors, rain sensors, and so forth. For example, the sensor system 1204 can be a camera system, the sensor system 1206 can be a LIDAR system, and the sensor system 1208 can be a RADAR system. Other examples may include any other number and type of sensors.

AV 1202 can also include several mechanical systems that can be used to maneuver or operate AV 1202. For instance, the mechanical systems can include vehicle propulsion system 1230, braking system 1232, steering system 1234, safety system 1236, and cabin system 1238, among other systems. Vehicle propulsion system 1230 can include an electric motor, an internal combustion engine, or both. The braking system 1232 can include an engine brake, a wheel braking system (e.g., a disc braking system that utilizes brake pads), hydraulics, actuators, and/or any other suitable componentry configured to assist in decelerating AV 1202. The steering system 1234 can include suitable componentry configured to control the direction of movement of the AV 1202 during navigation. Safety system 1236 can include lights and signal indicators, a parking brake, airbags, and so forth. The cabin system 1238 can include cabin temperature control systems, in-cabin entertainment systems, and so forth. In some examples, the AV 1202 may not include human driver actuators (e.g., steering wheel, handbrake, foot brake pedal, foot accelerator pedal, turn signal lever, window wipers, etc.) for controlling the AV 1202. Instead, the cabin system 1238 can include one or more client interfaces (e.g., Graphical User Interfaces (GUIs), Voice User Interfaces (VUIs), etc.) for controlling certain aspects of the mechanical systems 1230-1238.

AV 1202 can additionally include a local computing device 1210 that is in communication with the sensor systems 1204-1208, the mechanical systems 1230-1238, the data center 1250, and the client computing device 1270, among other systems. The local computing device 1210 can include one or more processors and memory, including instructions that can be executed by the one or more processors. The instructions can make up one or more software stacks or components responsible for controlling the AV 1202; communicating with the data center 1250, the client computing device 1270, and other systems; receiving inputs from riders, passengers, and other entities within the AV's environment; logging metrics collected by the sensor systems 1204-1208; and so forth. In this example, the local computing device 1210 includes a perception stack 1212, a mapping and localization stack 1214, a planning stack 1216, a control stack 1218, a communications stack 1220, a High Definition (HD) geospatial database 1222, and an AV operational database 1224, among other stacks and systems.

Perception stack 1212 can enable the AV 1202 to “see” (e.g., via cameras, LIDAR sensors, infrared sensors, etc.), “hear” (e.g., via microphones, ultrasonic sensors, RADAR, etc.), and “feel” (e.g., pressure sensors, force sensors, impact sensors, etc.) its environment using information from the sensor systems 1204-1208, the mapping and localization stack 1214, the HD geospatial database 1222, other components of the AV, and other data sources (e.g., the data center 1250, the client computing device 1270, third-party data sources, etc.). The perception stack 1212 can detect and classify objects and determine their current and predicted locations, speeds, directions, and the like. In addition, the perception stack 1212 can determine the free space around the AV 1202 (e.g., to maintain a safe distance from other objects, change lanes, park the AV, etc.). The perception stack 1212 can also identify environmental uncertainties, such as where to look for moving objects, flag areas that may be obscured or blocked from view, and so forth.

Mapping and localization stack 1214 can determine the AV's position and orientation (pose) using different methods from multiple systems (e.g., GPS, IMUS, cameras, LIDAR, RADAR, ultrasonic sensors, the HD geospatial database 1222, etc.). For example, in some examples, the AV 1202 can compare sensor data captured in real-time by the sensor systems 1204-1208 to data in the HD geospatial database 1222 to determine its precise (e.g., accurate to the order of a few centimeters or less) position and orientation. The AV 1202 can focus its search based on sensor data from one or more first sensor systems 1204 (e.g., GPS) by matching sensor data from one or more second sensor systems 1206 (e.g., LIDAR). If the mapping and localization information from one system is unavailable, the AV 1202 can use mapping and localization information from a redundant system and/or from remote data sources.

The planning stack 1216 can determine how to maneuver or operate the AV 1202 safely and efficiently in its environment. For example, the planning stack 1216 can receive the location, speed, and direction of the AV 1202, geospatial data, data regarding objects sharing the road with the AV 1202 (e.g., pedestrians, bicycles, vehicles, ambulances, buses, cable cars, trains, traffic lights, lanes, road markings, etc.) or certain events occurring during a trip (e.g., an Emergency Vehicle (EMV) blaring a siren, intersections, occluded areas, street closures for construction or street repairs, Double-Parked Vehicles (DPVs), etc.), traffic rules and other safety standards or practices for the road, user input, and other relevant data for directing the AV 1202 from one point to another. The planning stack 1216 can determine multiple sets of one or more mechanical operations that the AV 1202 can perform (e.g., go straight at a specified speed or rate of acceleration, including maintaining the same speed or decelerating; power on the left blinker, decelerate if the AV is above a threshold range for turning, and turn left; power on the right blinker, accelerate if the AV is stopped or below the threshold range for turning, and turn right; decelerate until completely stopped and reverse; etc.), and select the best one to meet changing road conditions and events. If something unexpected happens, the planning stack 1216 can select from multiple backup plans to carry out. For example, while preparing to change lanes to turn right at an intersection, another vehicle may aggressively cut into the destination lane, making the lane change unsafe. The planning stack 1216 could have already determined an alternative plan for such an event, and upon its occurrence, help to direct the AV 1202 to go around the block instead of blocking a current lane while waiting for an opening to change lanes.

The control stack 1218 can manage the operation of the vehicle propulsion system 1230, the braking system 1232, the steering system 1234, the safety system 1236, and the cabin system 1238. The control stack 1218 can receive sensor signals from the sensor systems 1204-1208 as well as communicate with other stacks or components of the local computing device 1210 or a remote system (e.g., the data center 1250) to effectuate operation of the AV 1202. For example, the control stack 1218 can implement the final path or actions from the multiple paths or actions provided by the planning stack 1216. This can involve turning the routes and decisions from the planning stack 1216 into commands for the actuators that control the AV's steering, throttle, brake, and drive unit.

The communication stack 1220 can transmit and receive signals between the various stacks and other components of the AV 1202 and between the AV 1202, the data center 1250, the client computing device 1270, and other remote systems. The communication stack 1220 can enable the local computing device 1210 to exchange information remotely over a network, such as through an antenna array or interface that can provide a metropolitan WIFI® network connection, a mobile or cellular network connection (e.g., Third Generation (3G), Fourth Generation (4G), Long-Term Evolution (LTE), 5th Generation (5G), etc.), and/or other wireless network connection (e.g., License Assisted Access (LAA), Citizens Broadband Radio Service (CBRS), MULTEFIRE, etc.). The communication stack 420 can also facilitate local exchange of information, such as through a wired connection (e.g., a user's mobile computing device docked in an in-car docking station or connected via Universal Serial Bus (USB), etc.) or a local wireless connection (e.g., Wireless Local Area Network (WLAN), Bluetooth®, infrared, etc.).

The HD geospatial database 1222 can store HD maps and related data of the streets upon which the AV 1202 travels. In some examples, the HD maps and related data can comprise multiple layers, such as an areas layer, a lanes and boundaries layer, an intersections layer, a traffic controls layer, and so forth. The areas layer can include geospatial information indicating geographic areas that are drivable (e.g., roads, parking areas, shoulders, etc.) or not drivable (e.g., medians, sidewalks, buildings, etc.), drivable areas that constitute links or connections (e.g., drivable areas that form the same road) versus intersections (e.g., drivable areas where two or more roads intersect), and so on. The lanes and boundaries layer can include geospatial information of road lanes (e.g., lane or road centerline, lane boundaries, type of lane boundaries, etc.) and related attributes (e.g., direction of travel, speed limit, lane type, etc.). The lanes and boundaries layer can also include 3D attributes related to lanes (e.g., slope, elevation, curvature, etc.). The intersections layer can include geospatial information of intersections (e.g., crosswalks, stop lines, turning lane centerlines, and/or boundaries, etc.) and related attributes (e.g., permissive, protected/permissive, or protected only left turn lanes; permissive, protected/permissive, or protected only U-turn lanes; permissive or protected only right turn lanes; etc.). The traffic controls layer can include geospatial information of traffic signal lights, traffic signs, and other road objects and related attributes.

The AV operational database 1224 can store raw AV data generated by the sensor systems 1204-1208 and other components of the AV 1202 and/or data received by the AV 1202 from remote systems (e.g., the data center 1250, the client computing device 1270, etc.). In some examples, the raw AV data can include HD LIDAR point cloud data, image or video data, RADAR data, GPS data, and other sensor data that the data center 450 can use for creating or updating AV geospatial data.

The data center 1250 can be a private cloud (e.g., an enterprise network, a co-location provider network, etc.), a public cloud (e.g., an IaaS network, a PaaS network, a SaaS network, or other CSP network), a hybrid cloud, a multi-cloud, and so forth. The data center 1250 can include one or more computing devices remote to the local computing device 1210 for managing a fleet of AVs and AV-related services. For example, in addition to managing the AV 1202, the data center 450 may also support a ridesharing service, a delivery service, a remote/roadside assistance service, street services (e.g., street mapping, street patrol, street cleaning, street metering, parking reservation, etc.), and the like.

The data center 1250 can send and receive various signals to and from the AV 1202 and the client computing device 1270. These signals can include sensor data captured by the sensor systems 1204-1208, roadside assistance requests, software updates, ridesharing pick-up and drop-off instructions, and so forth. In this example, the data center 1250 includes one or more of a data management platform 1252, an Artificial Intelligence/Machine Learning (AI/ML) platform 1254, a simulation platform 1256, a remote assistance platform 1258, a ridesharing platform 1260, and a map management platform 1262, among other systems.

Data management platform 1252 can be a “big data” system capable of receiving and transmitting data at high speeds (e.g., near real-time or real-time), processing a large variety of data, and storing large volumes of data (e.g., terabytes, petabytes, or more of data). The varieties of data can include data having different structures (e.g., structured, semi-structured, unstructured, etc.), data of different types (e.g., sensor data, mechanical system data, ridesharing service data, map data, audio data, video data, etc.), data associated with different types of data stores (e.g., relational databases, key-value stores, document databases, graph databases, column-family databases, data analytic stores, search engine databases, time series databases, object stores, file systems, etc.), data originating from different sources (e.g., AVs, enterprise systems, social networks, etc.), data having different rates of change (e.g., batch, streaming, etc.), or data having other heterogeneous characteristics. The various platforms and systems of the data center 1250 can access data stored by the data management platform 1252 to provide their respective services.

The AI/ML platform 1254 can provide the infrastructure for training and evaluating machine learning algorithms for operating the AV 1202, the simulation platform 1256, the remote assistance platform 1258, the ridesharing platform 1260, the map management platform 1262, and other platforms and systems. Using the AI/ML platform 1254, data scientists can prepare data sets from the data management platform 1252; select, design, and train machine learning models; evaluate, refine, and deploy the models; maintain, monitor, and retrain the models; and so on.

The simulation platform 1256 can enable testing and validation of the algorithms, machine learning models, neural networks, and other development efforts for the AV 1202, the remote assistance platform 1258, the ridesharing platform 1260, the map management platform 1262, and other platforms and systems. The simulation platform 1256 can replicate a variety of driving environments and/or reproduce real-world scenarios from data captured by the AV 1202, including rendering geospatial information and road infrastructure (e.g., streets, lanes, crosswalks, traffic lights, stop signs, etc.) obtained from the map management platform 1262; modeling the behavior of other vehicles, bicycles, pedestrians, and other dynamic elements; simulating inclement weather conditions, different traffic scenarios; and so on.

The remote assistance platform 1258 can generate and transmit instructions regarding the operation of the AV 1202. For example, in response to an output of the Al/ML platform 1254 or other system of the data center 1250, the remote assistance platform 1258 can prepare instructions for one or more stacks or other components of the AV 1202.

The ridesharing platform 1260 can interact with a customer of a ridesharing service via a ridesharing application 1272 executing on the client computing device 470. The client computing device 1270 can be any type of computing system, including a server, desktop computer, laptop, tablet, smartphone, smart wearable device (e.g., smart watch; smart eyeglasses or other Head-Mounted Display (HMD); smart ear pods or other smart in-ear, on-ear, or over-ear device; etc.), gaming system, or other general-purpose computing device for accessing the ridesharing application 1272. The client computing device 1270 can be a customer's mobile computing device or a computing device integrated with the AV 1202 (e.g., the local computing device 1210). The ridesharing platform 1260 can receive requests to be picked up or dropped off from the ridesharing application 1272 and dispatch the AV 1202 for the trip.

Map management platform 1262 can provide a set of tools for the manipulation and management of geographic and spatial (geospatial) and related attribute data. The data management platform 1252 can receive LIDAR point cloud data, image data (e.g., still image, video, etc.), RADAR data, GPS data, and other sensor data (e.g., raw data) from one or more AVs 1202, Unmanned Aerial Vehicles (UAVs), satellites, third-party mapping services, and other sources of geospatially referenced data. The raw data can be processed, and map management platform 1262 can render base representations (e.g., tiles (2D), bounding volumes (3D), etc.) of the AV geospatial data to enable users to view, query, label, edit, and otherwise interact with the data. Map management platform 1262 can manage workflows and tasks for operating on the AV geospatial data. Map management platform 1262 can control access to the AV geospatial data, including granting or limiting access to the AV geospatial data based on user-based, role-based, group-based, task-based, and other attribute-based access control mechanisms. Map management platform 1262 can provide version control for the AV geospatial data, such as to track specific changes that (human or machine) map editors have made to the data and to revert changes when necessary. Map management platform 1262 can administer release management of the AV geospatial data, including distributing suitable iterations of the data to different users, computing devices, AVs, and other consumers of HD maps. Map management platform 1262 can provide analytics regarding the AV geospatial data and related data, such as to generate insights relating to the throughput and quality of mapping tasks.

In some examples, the map viewing services of map management platform 1262 can be modularized and deployed as part of one or more of the platforms and systems of the data center 1250. For example, the AI/ML platform 1254 may incorporate the map viewing services for visualizing the effectiveness of various object detection or object classification models, the simulation platform 1256 may incorporate the map viewing services for recreating and visualizing certain driving scenarios, the remote assistance platform 1258 may incorporate the map viewing services for replaying traffic incidents to facilitate and coordinate aid, the ridesharing platform 1260 may incorporate the map viewing services into the client application 1272 to enable passengers to view the AV 1202 in transit en route to a pick-up or drop-off location, and so on.

In many examples, cold plate/heat dissipation 102 may be another portion of AV 1202. Other parts of system 100 may be comprised appropriately in various components and blocks of the figure.

### Example AV

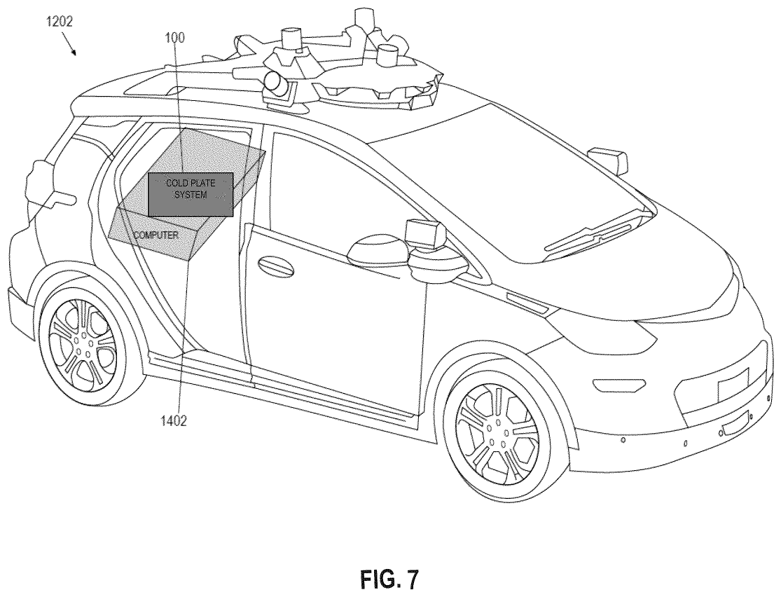

FIG. 7 is a schematic representation of an AV 1202 with example system 100, according to some examples of the present disclosure. Although AV 1202 is shown as a sedan, any suitable type of vehicle may be used with system 100 within the scope of the present disclosure. In various examples, one or more of IC devices as described in reference to FIG. 1 may be included within AV management system 1200 and/or computing system 1300 as described in reference to FIGS. 6 and 7. IC devices may include any suitable components that perform any or some of the functionalities as described in FIGS. 6 and 7. For example, one or more IC devices may comprise local computing device 1210. In another example, one or more IC devices may comprise part of control stack 1218.

In some examples, one or more functionalities of AV management system 1200 may be comprised in an on-board computer 1402. In various examples, computer 1402 may be an Automated Driving System Computer (ADSC). In such examples, one or more IC devices may include a microprocessor and/or other semiconductor IC devices of the ADSC. In many examples, given its size, computer 1402 may be installed in a trunk of AV 1202 or toward a rear of AV 1202, although it will be recognized that the features of examples described herein may be advantageously deployed in systems in which computer 1402 is enclosed in another area of AV 1202. Computer 1402 may be removably attached to the chassis of AV 1202 and/or otherwise coupled to other systems of AV 1202 by any number of wireless or wired communication pathways. In many examples, computer 1402 is configured to connect to various sensors of AV 1202 and store large amounts of vehicle camera and sensor data in different kinds of storage devices, including solid-state data storage devices.

### Selected Examples

Example 1 provides an apparatus comprising a printed circuit board (PCB) including at least one connector on a first surface thereof; a cold plate connected to the first surface of the PCB, the cold plate including at least one tube disposed in a first portion of the cold plate and at least one opening for receiving the at least one connector therethrough, the at least one opening disposed in a second portion of the cold plate; and a housing including a lower housing portion for supporting the PCB and the cold plate such that the PCB is between the lower housing portion and the cold plate and an upper housing portion over the first portion of the cold plate, wherein the second portion of the cold plate is exposed outside the upper housing portion when the upper and lower housing portions are fastened together.

Example 2 provides the apparatus of example 1, wherein the PCB is connected to cold plate via a thermally conductive material.

Example 3 provides the apparatus of example 2, wherein the thermally conductive material has adhesive properties.

Example 4 provides the apparatus of any of examples 1-3, wherein the at least one tube contains a liquid coolant.

Example 5 provides the apparatus of any of examples 1-4, further comprising a gasket in the at least one opening between an inside edge of the opening and an outside surface of the connector.

Example 6 provides the apparatus of example 5, wherein the gasket comprises at least one of rubber, silicone, metal, cork, felt, neoprene, nitrile rubber, fiberglass, polytetrafluoroethylene, and a plastic polymer.

Example 7 provides the apparatus of any of examples 1-6, further comprising a second PCB connected to the cold plate such that the first portion cold plate is between the first PCB and the second PCB and the second portion of the cold plate is not covered by the second PCB.

Example 8 provides the apparatus of any of examples 1-7, wherein the at least one connector comprises at least one of a network connector, a data connector, and a power connector.

Example 9 provides the apparatus of any of examples 1-8, wherein the at least one connector comprises a plurality of connectors and the at least one opening comprise a plurality of openings wherein each of the plurality of openings is configured to receive a respective one of the plurality of connectors.

Example 10 provides a cold plate for a computer system, the cold plate including at least one cooling tube in a first area thereof; and a plurality of openings in a second area thereof, wherein each of the plurality of openings has a shape to accommodate one of a plurality of connectors on a top surface of a printed circuit board (PCB) when the cold plate is connected to the top surface of the PCB.

Example 11 provides the cold plate of example 10, wherein each of the plurality of openings includes a gasket around an inside surface thereof.

Example 12 provides the cold plate of example 11, wherein the gasket forms a seal between the opening and the connector.

Example 13 provides the cold plate of any of examples 10-12, wherein at least one of the plurality of openings is at least partially surrounded by a recess in a surface of the cold plate.

Example 14 provides the cold plate of any of examples 10-13, wherein the at least one tube contains a liquid coolant.

Example 15 provides the cold plate of any of examples 10-14, further comprising at least one of aluminum, steel, and copper.

Example 16 provides the cold plate of any of examples 10-15, wherein the plurality of connectors comprises at least one of a network connector, a data connector, and a power connector.

Example 17 provides a method of assembling a computer system for an autonomous vehicle, the method comprising connecting a bottom surface of a cold plate to a top surface of a printed circuit board (PBC) using a thermally conductive material, the cold plate including a plurality of openings proximate an edge thereof, wherein each of the openings receives therethrough a corresponding one of a plurality of connectors on the PCB; and enclosing the PCB and the cold plate in a housing such that the portion of the cold plate including the openings is exposed outside the housing.

Example 18 provides the method of claim 17, wherein gaskets are provided between inside surfaces of the openings and outside surfaces of the connectors.

Example 19 provides the method of any of examples 17-18, further comprising connecting a second PCB to a top surface of the cold plate, the enclosing further comprising enclosing the second PCB within the housing.

Example 20 provides the method of any of examples 17-19, wherein the cold plate comprises at least one tube containing a liquid coolant, the enclosing further comprising enclosing the PCB and the cold pate such that a portion of the cold plate including the at least one tube is enclosed within the housing.

### Other Implementation Notes, Variations, and Applications

It is to be understood that not necessarily all objects or advantages may be achieved in accordance with any particular embodiment described herein. Thus, for example, those skilled in the art will recognize that certain embodiments may be configured to operate in a manner that achieves or optimizes one advantage or group of advantages as taught herein without necessarily achieving other objects or advantages as may be taught or suggested herein.

In one example embodiment, any number of electrical circuits of the figures may be implemented on a board of an associated electronic device. The board can be a general circuit board that can hold various components of the interior electronic system of the electronic device and, further, provide connectors for other peripherals. More specifically, the board can provide the electrical connections by which the other components of the system can communicate electrically. Any suitable processors (inclusive of digital signal processors, microprocessors, supporting chipsets, etc.), computer-readable non-transitory memory elements, etc. can be suitably coupled to the board based on particular configuration needs, processing demands, computer designs, etc. Other components such as exterior storage, additional sensors, controllers for audio/video display, and peripheral devices may be attached to the board as plug-in cards, via cables, or integrated into the board itself. In various embodiments, the functionalities described herein may be implemented in emulation form as software or firmware running within one or more configurable (e.g., programmable) elements arranged in a structure that supports these functions. The software or firmware providing the emulation may be provided on non-transitory computer-readable storage medium comprising instructions to allow a processor to carry out those functionalities.

It is also imperative to note that all of the specifications, dimensions, and relationships outlined herein (e.g., the number of processors, logic operations, etc.) have only been offered for purposes of example and teaching only. Such information may be varied considerably without departing from the spirit of the present disclosure, or the scope of the appended examples. The specifications apply only to one non-limiting example and, accordingly, they should be construed as such. In the foregoing description, example embodiments have been described with reference to particular arrangements of components. Various modifications and changes may be made to such embodiments without departing from the scope of the appended examples. The description and drawings are, accordingly, to be regarded in an illustrative rather than in a restrictive sense.

Note that with the numerous examples provided herein, interaction may be described in terms of two, three, four, or more components; however, this has been done for purposes of clarity and example only. It should be appreciated that the system can be consolidated in any suitable manner. Along similar design alternatives, any of the illustrated components, modules, and elements of the FIGS. may be combined in various possible configurations, all of which are clearly within the broad scope of this Specification.

Various operations may be described as multiple discrete actions or operations in turn in a manner that is most helpful in understanding the example subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

Note that in this Specification, references to various features (e.g., elements, structures, modules, components, steps, operations, characteristics, etc.) included in “one embodiment”, “example embodiment”, “an embodiment”, “another embodiment”, “some embodiments”, “various embodiments”, “other embodiments”, “alternative embodiment”, and the like are intended to mean that any such features are included in one or more embodiments of the present disclosure, but may or may not necessarily be combined in the same embodiments.

Numerous other changes, substitutions, variations, alterations, and modifications may be ascertained to one skilled in the art and it is intended that the present disclosure encompass all such changes, substitutions, variations, alterations, and modifications as falling within the scope of the appended examples. Note that all optional features of the systems and methods described above may also be implemented with respect to the methods or systems described herein and specifics in the examples may be used anywhere in one or more embodiments.

In order to assist the United States Patent and Trademark Office (USPTO) and, additionally, any readers of any patent issued on this application in interpreting the examples appended hereto, Applicant wishes to note that the Applicant: (a) does not intend any of the appended examples to invoke paragraph (f) of 35 U.S.C. Section 112 as it exists on the date of the filing hereof unless the words “means for” or “step for” are specifically used in the particular examples; and (b) does not intend, by any statement in the Specification, to limit this disclosure in any way that is not otherwise reflected in the appended examples.

What is claimed is:

1. An apparatus comprising:
a printed circuit board (PCB) including at least one connector on a first surface thereof;
a cold plate connected to the first surface of the PCB, the cold plate including:
at least one tube disposed in a first portion of the cold plate; and
at least one opening for receiving the at least one connector therethrough, the at least one opening disposed in a second portion of the cold plate; and
a housing including a lower housing portion for supporting the PCB and the cold plate such that the PCB is between the lower housing portion and the cold plate and an upper housing portion over the first portion of the cold plate,
wherein the second portion of the cold plate is exposed outside the upper housing portion when the upper and lower housing portions are fastened together.

2. The apparatus of claim 1, wherein the PCB is connected to cold plate via a thermally conductive material.

3. The apparatus of claim 2, wherein the thermally conductive material has adhesive properties.

4. The apparatus of claim 1, wherein the at least one tube contains a liquid coolant.

5. The apparatus of claim 1, further comprising a gasket in the at least one opening between an inside edge of the opening and an outside surface of the connector.

6. The apparatus of claim 5, wherein the gasket comprises at least one of rubber, silicone, metal, cork, felt, neoprene, nitrile rubber, fiberglass, polytetrafluoroethylene, and a plastic polymer.

7. The apparatus of claim 1, further comprising a second PCB connected to the cold plate such that the first portion cold plate is between the first PCB and the second PCB and the second portion of the cold plate is not covered by the second PCB.

8. The apparatus of claim 1, wherein the at least one connector comprises at least one of a network connector, a data connector, and a power connector.

9. The apparatus of claim 1, wherein the at least one connector comprises a plurality of connectors and the at least one opening comprise a plurality of openings wherein each of the plurality of openings is configured to receive a respective one of the plurality of connectors.

10. A cold plate for a computer system, the cold plate including:
at least one cooling tube in a first area thereof; and
a plurality of openings in a second area thereof, wherein each of the plurality of openings has a shape to accommodate one of a plurality of connectors on a top surface of a printed circuit board (PCB) when the cold plate is connected to the top surface of the PCB.

11. The cold plate of claim 10, wherein each of the plurality of openings includes a gasket around an inside surface thereof.

12. The cold plate of claim 11, wherein the gasket forms a seal between the opening and the connector.

13. The cold plate of claim 10, wherein at least one of the plurality of openings is at least partially surrounded by a recess in a surface of the cold plate.

14. The cold plate of claim 10, wherein the at least one tube contains a liquid coolant. The cold plate of claim 10, further comprising at least one of aluminum, steel, and copper.

16. The cold plate of claim 10, wherein the plurality of connectors comprises at least one of a network connector, a data connector, and a power connector.

17. A method of assembling a computer system for an autonomous vehicle, the method comprising:
connecting a bottom surface of a cold plate to a top surface of a printed circuit board (PBC) using a thermally conductive material, the cold plate including a plurality of openings proximate an edge thereof, wherein each of the openings receives therethrough a corresponding one of a plurality of connectors on the PCB; and
enclosing the PCB and the cold plate in a housing such that the portion of the cold plate including the openings is exposed outside the housing.

18. The method of claim 17, wherein gaskets are provided between inside surfaces of the openings and outside surfaces of the connectors.

19. The method of claim 17, further comprising connecting a second PCB to a top surface of the cold plate, the enclosing further comprising enclosing the second PCB within the housing.

20. The method of claim 17, wherein the cold plate comprises at least one tube containing a liquid coolant, the enclosing further comprising enclosing the PCB and the cold pate such that a portion of the cold plate including the at least one tube is enclosed within the housing.
